(19) United States
(12) Patent Application Publication
(10) Pub. No.: US 2022/0283503 A1
(43) Pub. Date: Sep. 8, 2022

(54) METHOD FOR MOUNTING AN OPTICAL SYSTEM

(71) Applicant: Carl Zeiss SMT GmbH, Oberkochen (DE)

(72) Inventors: Johann Dorn, Neu-Ulm (DE); Steffen Fritzsche, Aalen (DE); Wolfgang Grimm, Aalen (DE); Peter Nieland, Aalen (DE)

(21) Appl. No.: 17/804,193

(22) Filed: May 26, 2022

Related U.S. Application Data
(63) Continuation of application No. PCT/EP2020/081919, filed on Nov. 12, 2020.

(30) Foreign Application Priority Data
Dec. 5, 2019 (DE) 102019218925.3

(51) Int. Cl. G03F 7/20; G06F 30/10; G02B 27/00; G02B 27/62

(52) U.S. Cl. CPC G03F 7/705; G03F 7/70975; G03F 7/70833; G03F 7/70141; G06F 30/10; G02B 27/0012; G02B 27/62

(57) ABSTRACT

A method includes: a) measuring individual parts K1-KN of an optical system to provide measurement data, N being greater than one; b) using the measurement data to virtualize the individual parts K1-KN and using the virtualized individual parts K1-KN to generate an actual assembly model by geometrically stringing together a plurality of the virtualized individual parts K1-KN, the actual assembly model comprising virtual actual positions of the virtualized individual parts K1-KN in a virtually assembled state; c) using the actual assembly model and a target assembly model to determine a correction measure, the target assembly model comprising virtual target positions of one or more of the virtualized individual parts K1-KN in the virtually assembled state; and d) using the correction measure, assembling the individual parts K1-KN to form the optical system.

### CROSS-REFERENCE TO RELATED APPLICATIONS

The present application is a continuation of, and claims benefit under 35 USC 120 to, international application PCT/EP2020/081919, filed Nov. 12, 2020, which claims benefit under 35 USC 119 of German Application No. 10 2019 218 925.3, filed Dec. 5, 2019. The entire disclosure of each of these applications is incorporated by reference herein.

### FIELD

The present disclosure relates to a method for assembling an optical system, to a method for operating an optical system, to a data processing apparatus, and to a computer program product.

### BACKGROUND

Microlithography is used for producing microstructured components, such as for example integrated circuits. The microlithography process is performed using a lithography apparatus, which has an illumination system and a projection system. The image of a mask (reticle) illuminated via the illumination system is in this case projected via the projection system onto a substrate, for example a silicon wafer, which is coated with a light-sensitive layer (photoresist) and arranged in the image plane of the projection system, in order to transfer the mask structure to the light-sensitive coating of the substrate.

The construction of optical systems such as the projection system (which is also referred to as projection lens or projection optics box—POB) can involve exact positioning of optical surfaces and other functional faces (e.g., on stops or end stops) of the order of micrometers in all six degrees of freedom. In the process, direct measurement of the position of the functional faces in the installed state is often impossible.

Another issue can arise from the fact that the desired installation accuracy of the functional faces can be significantly lower than the manufacturing accuracy of the components or individual parts, or that it would involve much outlay to manufacture the functional faces very accurately in relation to the contact and reference faces. Therefore, it is common practice to insert tunable spacers at the interfaces of the individual parts to one another, for instance at contact faces or screwed connections. Should the initially installed set of spacers not lead to the desired positional accuracy of the functional face, this set can be replaced by a new set of spacers or adjusted on an individual basis, for example ground or polished. Typically, the six degrees of freedom are adjusted in succession, leading to a plurality of adjustment loops. Additional adjustment loops can be caused by the circumstances of the effective directions of the spacers often not being orthogonal to one another, that is to say not being decoupled from one another. This can increase the time involved to manufacture the optical system, and hence the costs. This can be especially true if spacers have to be adjusted on an individual basis, that is to say have to be manufactured to predetermined dimensions.

### SUMMARY

The present disclosure seeks to provide an improved approach.

Accordingly, a first aspect proposes a method for assembling an optical system, for example a lithography apparatus, including the steps of:

a) measuring individual parts K1-KN of the optical system for the purposes of providing measurement data, where N>1,

b) virtualizing the individual parts K1-KN with the aid of the provided measurement data and generating an actual assembly model from the virtualized individual parts K1-KN, the actual assembly model containing virtual actual positions of the virtualized individual parts K1-KN in a virtually assembled state,

c) determining a correction measure on the basis of the actual assembly model and a target assembly model, the target assembly model containing virtual target position of one or more of the virtualized individual parts K1-KN in the virtually assembled state, and

d) assembling the individual parts K1-KN to form the optical system using the correction measure.

As a result, the adjustment loops described at the outset are largely avoided. Moreover, it is possible to undertake a correction at only one position or only at a few positions, the correction then leading to the desired target position of the functional face (on one of the individual parts K1-KN). Thus, there is no need for highly accurate manufacture of all individual parts. Moreover, this also can allow for a highly accurate adjustment of the relative position of a functional face that is no longer reachable by a metrological approach post assembly. For example, this consequently can allow the tolerances of the involved components or individual parts and of the assembly processes to be relaxed, and hence it is possible to reduce development outlay (e.g., the development of precise tools) and production costs (throughputs time, rejects, individual part costs).

The optical system may be a lithography apparatus or a part thereof, for instance an illumination system or projection system.

The measurement according to step a) can include a measurement of, for example, mechanical properties (for example, measures, dimensions, tolerances, etc.), optical properties (reflectivity and so on) and/or thermal properties of a respective individual part. The measurement can be implemented mechanically or optically, for example.

In this case, “data” refers to electronic data.

“Virtualizing the individual parts K1-KN” refers to the generation of data that describe the individual parts K1-KN. These data are able to describe the individual parts K1-KN via points, surfaces, coordinate systems or three-dimensional bodies.

“Generating an actual assembly model” refers to additional data being added to the electronic data describing the individual parts K1-KN, the additional data describing the relationships of the virtualized individual parts K1-KN such that virtual actual positions of the virtualized individual parts K1-KN in a virtually assembled state of same arise. These additional data may be construction data that originate from a CAD (computer aided design) model. The CAD model may comprise geometric, mechanical, optical and/or thermal properties, parameters and/or interfaces (between the individual parts).

By way of example, the actual assembly model is generated by geometric stringing together of a plurality of the virtualized individual parts K1-KN.

In embodiments, the actual assembly model for example also contains mechanical relationships between the virtualized individual parts K1-KN in addition to the virtual actual positions of the virtualized individual parts K1-KN in a virtually assembled state.

The target assembly model may contain data originating from, or being derived from, the CAD model. The target assembly model usually contains at least the (ideal or sought-after) positions of the one or more functional faces of one or more individual parts, but may also describe positions of other individual parts (without functional faces).

To the extent reference is presently made to an actual and/or target position of one or more of the virtualized individual parts K1-KN, this means the actual and/or target position of one or more points, faces and/or three-dimensional bodies (e.g., a tetrahedral mesh) of the one or more virtualized individual parts K1-KN.

The determined correction measure can be designed in such a way that the latter acts on a geometric and/or mechanical relationship of at least two of the individual parts K1-KN with respect to one another. That is to say the correction measure for example can influence a relative position and/or alignment of the at least two individual parts.

The assembly comprises connecting, for example joining, of the individual parts K1-KN to one another, for example in interlocking, force-fit and/or cohesive fashion. In the present case, “connecting” should be understood to refer to an interlocking, force-fit or integrally bonded connection, or a combination thereof. An interlocking connection is obtained by at least two connection partners engaging one inside the other or one behind the other. A force-fit connection, for instance screwed connection, presupposes a normal force on the surfaces to be connected to one another. Force-fit connections can be obtained by frictional engagement. The mutual displacement of the faces is prevented as long as the counterforce brought about by the static friction is not exceeded. A force-locking connection can also be present as a magnetic force-locking engagement. In cohesive connections, the connection partners are held together by atomic or molecular forces. Cohesive connections are non-releasable connections that can be separated only by destruction of the connection mechanism. A cohesive connection enables connection by, e.g., adhesive bonding, soldering, welding or vulcanization.

N is an integer greater than 1.

According to an embodiment, the method includes:

generating the actual assembly model by geometric stringing together of the virtualized individual parts K1-KN, and

determining the correction measure in step c) on the basis of a comparison between the virtual actual position of the virtualized individual part KN and the virtual target position of the virtualized individual part KN.

This describes what is known as the virtual contact assembly. According to a variant of the virtual contact assembly, the location that a functional face will be arranged at when all individual parts are installed according to their geometric measurement data is determined. It is also possible to include margins, which for example consider shape changes of the individual parts. Shape changes may result from different mounts and different masses of the individual parts or assemblies. By way of example, when a projection lens is constructed, a force frame can be mounted first, the latter being successively filled with modules and therefore experiencing load changes and hence shape changes.

According to a further embodiment, the method includes:

generating the actual assembly model by fixing the virtualized individual parts K1 and KN at their target position from the target assembly model,

geometrically stringing together the virtualized individual parts K2-KN-1 with K1 and/or KN, and

determining the correction measure in step c) on the basis of virtual actual positions of at least two virtualized individual parts K2-KN-1.

This describes the virtual target point assembly. Within the scope of the latter, remaining gaps can emerge directly—to be precise between those (two or more) individual parts (of the individual parts K2-KN) which are not in contact at the end of the stringing-together process.

According to a further embodiment, the correction measure in step d) is applied to the individual part KN-1 or to a region, for example a gap, between the individual parts KN-1 and KN.

The correction can be implemented adjacent to the individual part KN (which has the functional face for example). There is an increased probability of tolerance errors having compensated one another up to the individual part KN-1.

According to a further embodiment, the individual part KN comprises: an optical element, for example a mirror, a lens element, an optical grating and/or a waveplate, a stop, a sensor and/or an end stop.

These designate examples of an individual part KN with functional faces.

Alternatively, the individual part KN may be a mechanical component, a mechatronic component, for example an actuator, and/or a bearing.

According to a further embodiment, the individual part KN-1 comprises: a mechanical component, a mechatronic component, for example an actuator, and/or a bearing.

The defect correction can be implemented on such components as it is easily possible-for example by adjusting an operating range of an actuator. In this case, “mechanical components” comprise for example a mechanical reference face or a fit, for example alignment pins or alignment holes. In this case, a “bearing” comprises for example a mechanical and/or magnetic bearing, for instance a weight compensator for optical elements.

According to a further embodiment, the correction measure includes: inserting a spacer, for example between two of the individual parts K1-KN, adjusting a play of a fastening mechanism which for example fastens two of the individual parts K1-KN to one another, and/or adjusting an operating point of a mechatronic component, for example of an actuator as constituent part of one of the individual parts K1-KN.

According to a further embodiment, the correction measure in step c) is determined on the basis of an available actuator travel of the actuator.

According to a further embodiment, N>5 or 10.

According to a further embodiment, a gap between two of the individual parts K1-KN is determined in step c) and a spacer is inserted into the gap in step d).

The spacer can be a spacer mechanism, a shim, etc., for example made of metal or ceramics. Alternatively or in addition, the spacer may be adjustable in respect of the space defined thereby, for example in respect of its thickness, for example it may be provided in the form of a setting screw or mutually displaceable wedges. In embodiments, the spacer may be removed again following the assembly, that is to say after step d) for example.

According to a further embodiment, the correction measure according to step c) relates at least to a first and a second degree of freedom.

According to a further embodiment, the correction measure is applied in step d), to a first of the individual parts K1-KN or between a first pair of individual parts K1-KN for the first degree of freedom and to a second of the individual parts K1-KN or between a second pair of individual parts K1-KN for the second degree of freedom.

As a result of the correction measures being divided among different individual parts, the former can be determined more easily (mutual influencing of the correction measures is avoided or reduced).

According to a further embodiment, the method includes:

measuring the assembled optical system for the provision of assembly measurement data,

determining a further correction measure on the basis of a comparison between the assembly measurement data and the target assembly model, and

aligning one or more of the individual parts K1-KN on the basis of the determined further correction measure.

At this point there is a further correction by comparing the assembled optical system with the target assembly model.

According to a further embodiment, the actual assembly model is determined with the aid of analytic geometry, for example, homogenous coordinates and/or Euler angles.

This can be easily implementable, for example on a computer device such as a microprocessor.

A second aspect proposes a method for operating an optical system, for example a lithography apparatus, including the steps of:

a) measuring individual parts K1-KN of the optical system for the purposes of providing measurement data, where N>1,

b) virtualizing the individual parts K1-KN with the aid of the provided measurement data and generating an actual assembly model from the virtualized individual parts K1-KN, the actual assembly model containing virtual actual positions of the virtualized individual parts K1-KN in a virtually assembled state,

c) determining a correction measure on the basis of the actual assembly model and a target assembly model, the target assembly model containing virtual target positions of one or more of the virtualized individual parts K1-KN in the virtually assembled state, and

d) assembling the individual parts K1-KN to form the optical system and operating the optical system using the correction measure.

Operating the optical system refers to the use thereof for its intended purpose. For example, operating the optical system means the implementation of exposure processes using same, for example the exposure of wafers for manufacturing microchips. The manufacturing defects (tolerances) can be corrected here with the aid of an appropriate adjustment of the controller of the optical system for example. By way of example, a travel or operating point of an actuator during operation may be provided such that the correction is attained.

The method according to the second aspect can be combined with that of the first aspect such that correction measures are initially determined during the assembly and during the operation, and are then applied during the assembly or during the operation.

The following is therefore provided according to a third aspect: a method for assembling and/or for operating an optical system, for example a lithography apparatus, includes the steps of:

a) measuring individual parts K1-KN of the optical system for the purposes of providing measurement data, where N>1,

b) virtualizing the individual parts K1-KN with the aid of the provided measurement data and generating an actual assembly model from the virtualized individual parts K1-KN, the actual assembly model containing virtual actual positions of the virtualized individual parts K1-KN in a virtually assembled state,

c) determining a correction measure on the basis of the actual assembly model and a target assembly model, the target assembly model containing virtual target positions of one or more of the virtualized individual parts K1-KN in the virtually assembled state, and

d) assembling the K1-KN individual parts to form the optical system using the correction measure and/or operating the optical system using the correction measure.

A fourth aspect proposes a data processing apparatus comprising:

a virtualization unit for virtualizing individual parts K1-KN of an optical system with the aid of provided measurement data and generating an actual assembly model from the virtualized individual parts K1-KN, the actual assembly model containing virtual actual positions of the virtualized individual parts K1-KN in a virtually assembled state, and

a determination unit for determining a correction measure for application during an assembly of the optical system from the individual parts K1-KN or during an operation of the optical system assembled from the individual parts K1-KN, on the basis of the actual assembly model and a target assembly model, the target assembly model containing virtual target positions of one or more of the virtualized individual parts K1-KN in the virtually assembled state.

The respective device or unit, for example the measuring device, computer device, virtualization unit or determination unit, may be implemented in terms of hardware and/or software. In the case of an implementation in terms of hardware technology, the respective unit can be embodied as a device or as part of a device, for example as a computer or as a microprocessor. In the case of an implementation in terms of software technology, the respective device or unit can be embodied as a computer program product, as a function, as a routine, as part of a program code or as an executable object.

A fifth aspect proposes a computer program product prompting the implementation of the following steps on at least one program-controlled device:

virtualizing individual parts K1-KN of an optical system with the aid of provided measurement data and generating an actual assembly model from the virtualized individual parts K1-KN, the actual assembly model containing virtual actual positions of the virtualized individual parts K1-KN in a virtually assembled state, and

determining a correction measure for application during an assembly of the optical system from the individual parts K1-KN or during an operation of the optical system assembled from the individual parts K1-KN, on the basis of the actual assembly model and a target assembly model, the target assembly model containing virtual target positions of one or more of the virtualized individual parts K1-KN in the virtually assembled state.

A computer program product, such as e.g. a computer program, can be provided or supplied, for example, as a storage medium, such as e.g. a memory card, a USB stick, a CD-ROM, a DVD, or else in the form of a downloadable file from a server in a network. By way of example, in a wireless communications network, this can be effected by transferring an appropriate file with the computer program product.

“A(n); one” in the present case should not necessarily be understood to be restrictive to exactly one element. Rather, a plurality of elements, such as, for example, two, three or more, can also be provided. Any other numeral used here, too, should not be understood to the effect that there is a restriction to exactly the stated number of elements. Rather, numerical deviations upwards and downwards are possible, unless indicated to the contrary. Labeling the method steps with a), b), etc., should not be construed as restrictive to a certain sequence. The steps may also be relabeled, for example step b) becomes step f), for example for the purposes of inserting a preceding or subsequent step or an intermediate step.

The embodiments and features described for the method according to the first aspect correspondingly apply to the proposed method according to the second and third aspects, the data processing apparatus and the computer program product, and vice versa.

Further possible implementations of the disclosure also comprise not explicitly mentioned combinations of any features or embodiments that are described above or below with respect to the exemplary embodiments. In this case, a person skilled in the art will also add individual aspects as improvements or supplementations to the respective basic form of the disclosure.

Further refinements and aspects of the disclosure are the subject matter of the dependent claims and also of the exemplary embodiments of the disclosure described below.

### BRIEF DESCRIPTION OF THE DRAWINGS

In the text that follows, the disclosure will be explained in more detail on the basis of embodiments with reference to the accompanying figures, in which:

FIG. 1A shows a schematic view of an embodiment of an EUV lithography apparatus;

FIG. 1B shows a schematic view of an embodiment of a DUV lithography apparatus;

FIG. 2 shows a data processing apparatus for use in a method for assembling and for operating an optical system;

FIG. 3 shows an embodiment of a contact assembly model;

FIG. 4 shows an embodiment of a target point assembly model;

FIG. 5 shows the insertion of spacers for correcting different degrees of freedom in an optical system in one embodiment;

FIG. 6 shows an exemplary displacement and rotation of individual parts using homogenous coordinates; and

FIG. 7 shows a flowchart of a method for assembling and optionally operating an optical system according to one embodiment.

### DETAILED DESCRIPTION

Unless indicated to the contrary, elements that are the same or functionally the same have been provided with the same reference signs in the figures. It should also be noted that the illustrations in the figures are not necessarily true to scale.

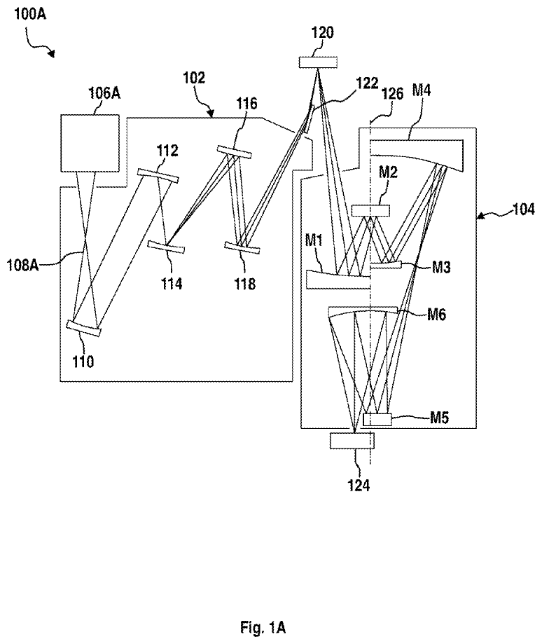

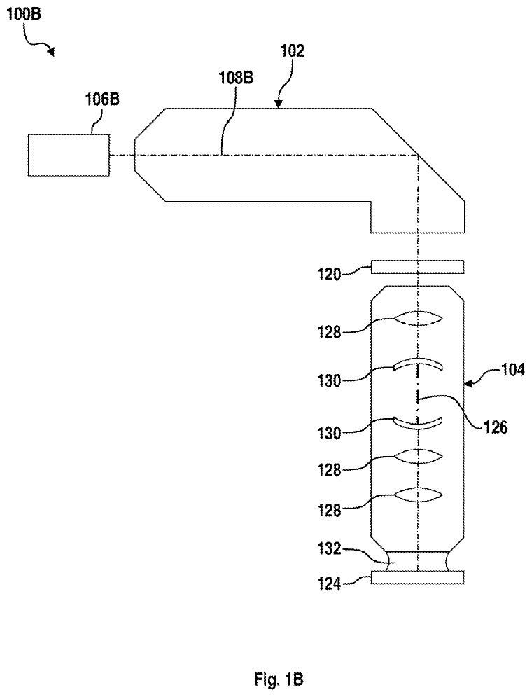

FIG. 1A shows a schematic view of an EUV lithography apparatus 100A comprising a beam-shaping and illumination system 102 and a projection system 104. In this case, EUV stands for “extreme ultraviolet” and denotes a wavelength of the working light of between 0.1 nm and 30 nm. The beam-shaping and illumination system 102 and the projection system 104 are respectively provided in a vacuum housing (not shown), wherein each vacuum housing is evacuated with the aid of an evacuation apparatus (not shown). The vacuum housings are surrounded by a machine room (not shown), in which drive apparatuses for mechanically moving or setting optical elements are provided. Furthermore, electrical controllers and the like may also be provided in the machine room.

The EUV lithography apparatus 100A has an EUV light source 106A. A plasma source (or a synchrotron), which emits radiation 108A in the EUV range (extreme ultraviolet range), that is to say for example in the wavelength range of 5 nm to 20 nm, can for example be provided as the EUV light source 106A. In the beam-shaping and illumination system 102, the EUV radiation 108A is focused and the desired operating wavelength is filtered out from the EUV radiation 108A. The EUV radiation 108A generated by the EUV light source 106A has a relatively low transmissivity through air, for which reason the beam-guiding spaces in the beam-shaping and illumination system 102 and in the projection system 104 are evacuated.

The beam-shaping and illumination system 102 illustrated in FIG. 1A has five mirrors 110, 112, 114, 116, 118. After passing through the beam-shaping and illumination system 102, the EUV radiation 108A is guided onto a photomask (reticle) 120. The photomask 120 is likewise embodied as a reflective optical element and can be arranged outside the systems 102, 104. Furthermore, the EUV radiation 108A may be directed onto the photomask 120 via a mirror 122. The photomask 120 has a structure which is imaged onto a wafer 124 or the like in a reduced fashion via the projection system 104.

The projection system 104 (also referred to as a projection lens) has six mirrors M1 to M6 for imaging the photomask 120 onto the wafer 124. In this case, individual mirrors M1 to M6 of the projection system 104 may be arranged symmetrically in relation to an optical axis 126 of the projection system 104. It should be noted that the number of mirrors M1 to M6 of the EUV lithography apparatus 100A is not restricted to the number shown. A greater or lesser number of mirrors M1 to M6 may also be provided. Furthermore, the mirrors M1 to M6 are generally curved on their front sides for beam shaping.

FIG. 1B shows a schematic view of a DUV lithography apparatus 100B, which comprises a beam-shaping and illumination system 102 and a projection system 104. In this case, DUV stands for “deep ultraviolet” and denotes a wavelength of the working light of between 30 nm and 250 nm. As has already been described with reference to FIG. 1A, the beam-shaping and illumination system 102 and the projection system 104 may be arranged in a vacuum housing and/or be surrounded by a machine room with corresponding drive apparatuses.

The DUV lithography apparatus 100B has a DUV light source 106B. By way of example, an ArF excimer laser that emits radiation 108B in the DUV range at 193 nm, for example, can be provided as the DUV light source 106B.

The beam-shaping and illumination system 102 illustrated in FIG. 1B guides the DUV radiation 108B onto a photomask 120. The photomask 120 is formed as a transmissive optical element and may be arranged outside the systems 102, 104. The photomask 120 has a structure which is imaged onto a wafer 124 or the like in a reduced fashion via the projection system 104.

The projection system 104 has a plurality of lens elements 128 and/or mirrors 130 for imaging the photomask 120 onto the wafer 124. In this case, individual lens elements 128 and/or mirrors 130 of the projection system 104 may be arranged symmetrically in relation to an optical axis 126 of the projection system 104. It should be noted that the number of lens elements 128 and mirrors 130 of the DUV lithography apparatus 100B is not restricted to the number shown. A greater or lesser number of lens elements 128 and/or mirrors 130 can also be provided. Furthermore, the mirrors 130 are generally curved on their front sides for beam shaping.

An air gap between the last lens element 128 and the wafer 124 can be replaced by a liquid medium 132 having a refractive index>1. The liquid medium 132 may be for example high-purity water. Such a structure is also referred to as immersion lithography and has an increased photolithographic resolution. The medium 132 can also be referred to as an immersion liquid.

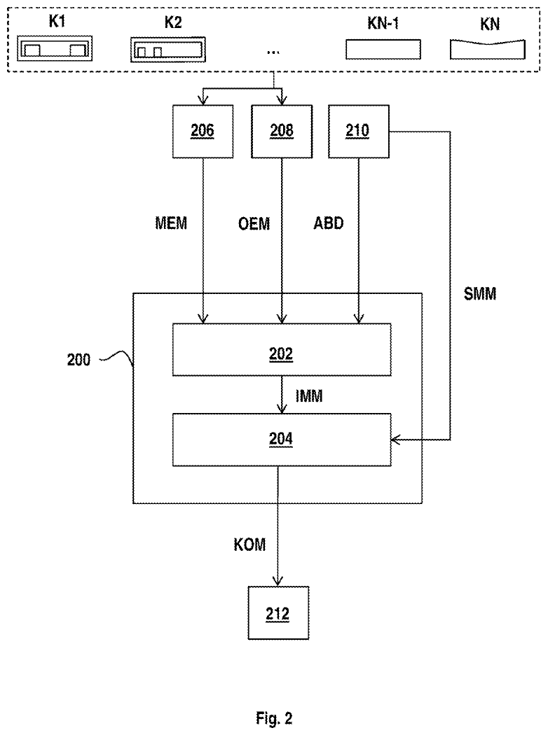

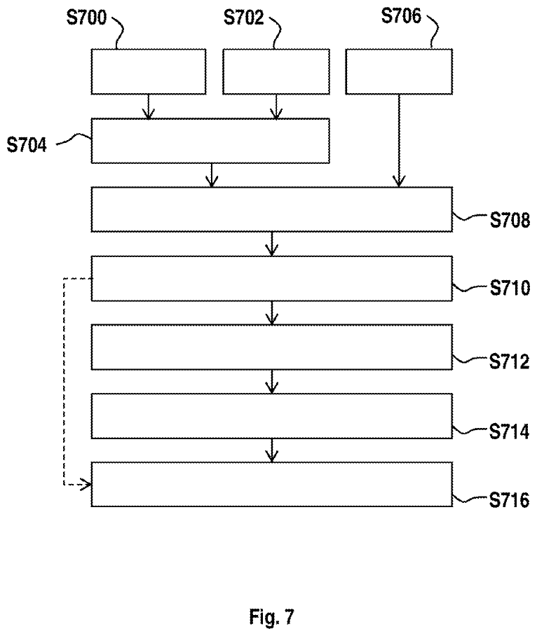

FIG. 2 shows a data processing apparatus 200 for use in a method for assembling and operating a projection system or projection lens 104 (for example according to FIG. 1A or 1B) or any other optical system. A flowchart for the method is shown in FIG. 7.

The data processing apparatus 200 is for example in the form of a computer device including a microprocessor and associated memory, for instance RAM, ROM, etc. The data processing apparatus 200 comprises a virtualization unit 202 and a determination unit 204. The units 202, 204 can be implemented in terms of hardware and/or software, i.e., in the form of program code.

Mechanical measurement data MEM and optional optical measurement data OEM are provided for the virtualization unit 202. Additionally, it may also be provided with further measurement data, for instance thermal measurement data.

The mechanical measurement data describe at least the geometry of a respective individual part K1 to KN. The individual parts K1 to KN are shown in exemplary fashion in a not yet assembled state in FIG. 2 and are assembled to form the projection lens 104 (see FIGS. 1A, 1B, 3 and 4) in an assembly step that will still be described in more detail below. The individual parts K1 to KN can be single parts or assemblies (composed of a plurality of respective single parts that have been interconnected).

The optical measurement data OEM describe optical properties of one or more of the individual parts K1 to KN. The following should be mentioned here as examples: a relative position of the optical axis or optical face, an (optionally spatially resolved) reflectivity, an (optionally also spatially resolved) transmission.

The mechanical measurement data MEM may have been acquired (S700 in FIG. 7) and provided, for example, by a measuring device 206, for instance a coordinate measuring machine (CMM), the latter (in actual fact) mechanically measuring the individual parts K1 to KN to this end. The optical measurement data OEM may likewise have been acquired (step S702) and provided by a measuring device 208, for instance an interferometer, the latter (in actual fact) optically measuring the individual parts K1 to KN.

The virtualization unit 202 generates virtualized individual parts K1-KN (S704 in FIG. 7) from the provided measurement data MEM, OEM. This should be understood to mean a mathematical, for example geometric description of the (real) individual parts K1-KN, for example in the form of matrices, which is stored in a data memory.

Furthermore, construction data ABD are provided for the virtualization unit 202. The construction data ABD describe at least geometric and possibly mechanical connections, interfaces and contact faces between the virtualized individual parts K1 to KN in the yet to be created virtual actual assembly model IMM. In this case, the geometric connections or geometric interfaces reproduce real connections or interfaces, for example a fastening mechanism between the individual parts K1-KN to be assembled.

The construction data ABD may be provided from a CAD (computer aided design) program and/or from an optics design program (S706 in FIG. 7). By way of example, this software may be operated on a computer device 210.

The virtualization unit 202 generates a (virtual) actual assembly model IMM (S708 in FIG. 7) from the virtualized individual parts K1 to KN and the construction data ABD. The individual parts K1 to KN are virtually assembled on one another in the actual assembly model IMM, with the relationships, for example geometric arrangement, of the individual parts K1 to KN with respect to one another being defined by the construction data ABD, for example via the contact face and interface information described therein.

The actual assembly model IMM can be generated in different ways, with the subsequently determined correction measure KOM then being geared to the corresponding model. As a matter of principle, the correction measure KOM is determined from the actual assembly model IMM and a target assembly model SMM, for example by a comparison of the two models IMM, SMM.

The target assembly model SMM describes virtual target positions of one or more of the virtualized individual parts K1-KN in the virtually assembled state. In this case, the target assembly model SMM assumes idealized individual parts K1-KN, that is to say those which for example exactly correspond to the CAD model. In this case, the idealized individual parts K1 to KN are linked, for example geometrically linked, to one another via the construction data ABD. The target assembly model SMM can likewise be provided from the CAD (computer aided design) program and/or from an optics design program, that is to say, for example, with the aid of the computer device 210. The correction measures KOM may be provided in the form of data for example to a CNC (computer numerical controlled) milling device 212. Depending on the correction measure or the appropriate data, the CNC milling device 212 mills suitable spacers 304 (see the explanations below) or other compensation elements in automated fashion.

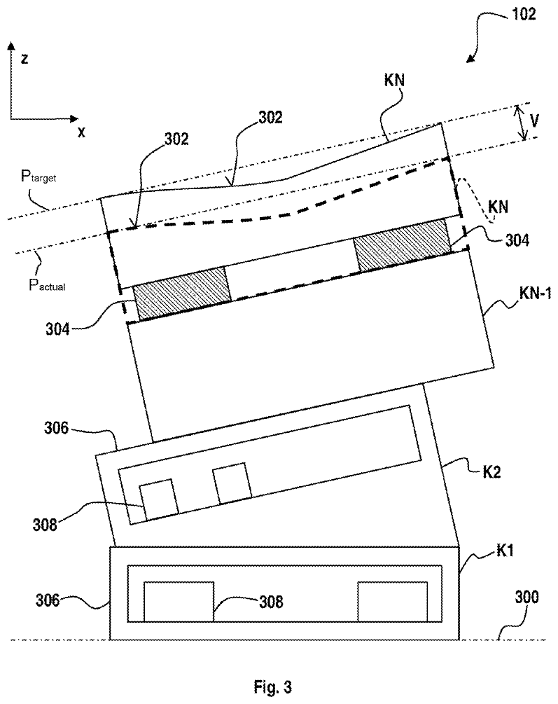

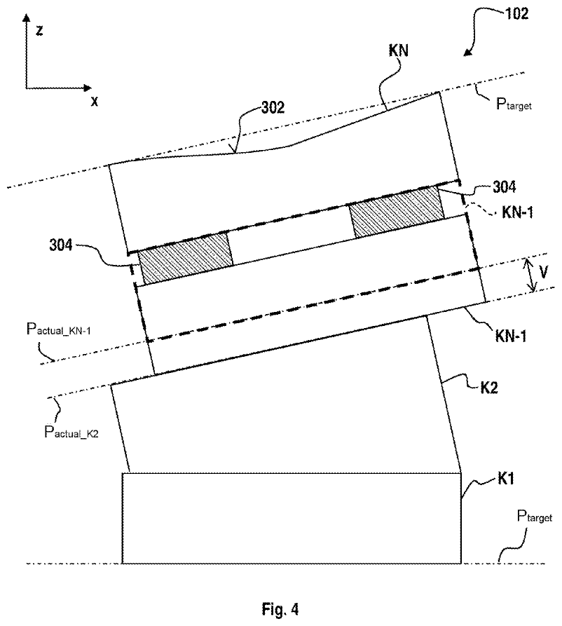

Below, a contact assembly model is initially explained in conjunction with FIG. 3, after which a target point assembly model is described with reference to FIG. 4.

According to the contact assembly model, the virtualized individual parts K1 to KN are geometrically strung together, stacked on one another in the exemplary embodiment. In this case, a base 300 is chosen, for example for the individual part K1. The following individual parts K2 to KN are stacked on one another while taking account of the construction data ABD, that is to say K2 is placed on K1, K3 is placed on K2, . . . , KN is placed on KN-1.

By way of example, the individual part KN is chosen in such a way that it is such a component that has what is known as a functional face. This means faces critical to the function of the lithography apparatus, for example optical faces or end stops, that is to say stops that limit the maximum movement of optical elements. Therefore, the individual part KN is for example an optical element, for example a mirror, a lens element, an optical grating or a waveplate. In the exemplary embodiment, the individual part KN is a mirror with an optically effective face 302 (optical footprint).

What now arises by way of stacking the individual parts K1 to KN on one another is that the individual part KN or its functional face (optically effective face 302) is arranged at an actual position P_{actual}. In FIG. 3, the individual part KN is depicted in this position using dashed lines.

The determination unit 204 (see FIG. 2) compares the actual position P_{actual} with a target position P_{target} from the target assembly model SMM. FIG. 3 shows the target position P_{target} of the individual part KN using a solid line. In the present case there is a deviation between P_{actual} and P_{target} in the form of an offset or gap V in the x-direction (that is to say, for example, in the plane of the plane of maximum extent of the optically effective face 302) and z-direction, for example the vertical direction, that is to say for example perpendicular to the plane of maximum extent of the optically effective face 302. Accordingly, as a correction measure, the determination unit 204 determines the insertion of one or more spacers 304, which may be in the form of spacer mechanisms, shims, etc., for example made of metal and/or ceramics, in a step S710 (FIG. 7).

The spacers 304 can be inserted between the individual part KN and the underlying individual part KN-1. In this case, N can be greater than 5 or greater than 10. Further alternatively, the correction measure can be carried out on the individual part KN itself, for example by way of appropriate material ablation therefrom.

Further optionally, the individual part KN-1 is a mechatronic component, for example an actuator, and/or a bearing. Actuators for example can be set in such a way that they provide the correction measure. By way of example, in the case of the exemplary embodiment of FIG. 3, an actuator KN-1 can be set in view of its operating range or operating point so that it compensates the offset or gap V. However, the (maximum) available actuator travel of the actuator should be taken into account in the process. In this case (should the actuator travel be insufficient) the spacers 304 are therefore not required (although this would probably tend to be the exception). Rather, the actuator KN-1 is actuated accordingly during the operation (step S716 in FIG. 7) of the lithography apparatus (100A, 100B). In this case, steps 5712 and 5714 are optionally dispensed with, as indicated in FIG. 7 by the dashed connection line; the projection lens 104 is assembled without the application of correction measures.

By way of example, the same also applies to a bearing KN-1. By way of example, bearings may include a screwing mechanism, with the aid of which they are easily adjustable. A corresponding procedure may also be implemented in the case of a fastening mechanism, for instance a screwed connection. By way of example, a screw is tightened with less torque in order to compensate the offset or gap V. Further alternatively, a sensor can monitor or verify the correction measure.

The above-described, determined correction measures can optionally be verified in the virtual actual assembly model IMM. To this end, the actual assembly model IMM is generated again—with application of the determined correction measure—and step S710 is repeated.

Subsequently, the projection lens 104 is assembled from the individual parts K1 to KN (S712 in FIG. 7), with the determined correction measures being applied. For example, the latter are implemented during the assembly of the projection lens 104, that is to say the above-described spacers 304 are manufactured and inserted into the gap V (FIG. 3) when putting together the individual parts K1-KN. Alternatively or in addition, these are applied during the operation of, for example, the lithography apparatus 100A, 100B with the projection lens 104, for instance as explained above for the actuator. In an optional step S714, the assembled projection lens 104 is measured (in actual fact), with the determined assembly measurement data being used for determining further correction measures, for example an insertion of spacers. For example, this can be implemented by comparing the assembly measurement data with the target assembly model SMM.

Furthermore, FIG. 3 illustrates that individual or all of the individual parts K1-KN can be in the form of assemblies. By way of example, the individual parts K1 and K2 each comprise a force frame 306, to which for example one or more optical elements 308, for example mirrors or lens elements, are fastened.

The aforementioned target point assembly model is explained below on the basis of FIG. 4. Therein, the virtualized individual parts K1 and KN are fixed at their target positions P_{target} from the target assembly model SMM. Subsequently, the individual parts K2, K3 (not depicted here), etc. are stacked on the individual part K1, and the individual parts KN-X, . . . , KN-1 (not depicted here) are stacked under the individual part KN. In this case, X is a number to be determined from the design. Hence, actual positions P_{actual_KN-1} (depicted using dashed lines in FIG. 4) for the individual part KN-1 and P_{actual_K2} for the individual part K2 arise in the exemplary embodiment. The determination unit 204 then determines the offset or gap V between the actual positions P_{actual_KN-1} and P_{actual_K2} and determines as a correction measure the insertion of the spacers 304 between the individual parts KN and KN-1 such that the offset or gap V is canceled and the individual parts KN-1 and K2 are arranged to one another in the arrangement defined by the construction data ABD. The new position of the individual part KN-1 arising as a result is depicted by a solid line in FIG. 4.

Otherwise, the features described in FIG. 3 apply accordingly to FIG. 4.

In the exemplary embodiments according to FIGS. 3 and 4, the correction measures only relate to two degrees of freedom, specifically the translational directions x and z. Naturally, the correction measure may relate to each of the six (three rotational and three translational) degrees of freedom, and may also relate to several of these degrees of freedom at the same time.

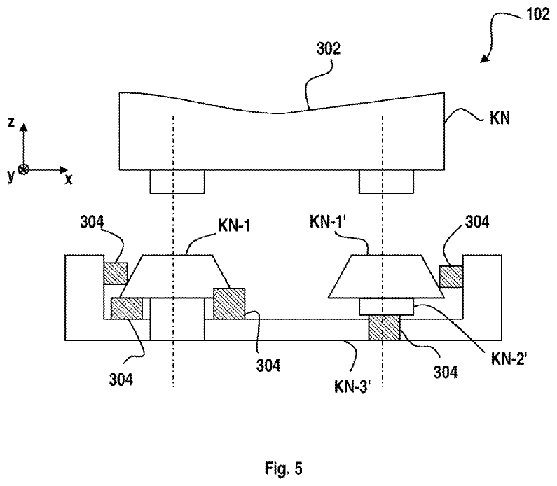

Thus, FIG. 5 for example shows the insertion of spacers 304 for the purposes of correcting a respective offset or gap V in the x-, y- and z-direction. In this case, a correction measure relating to the correction in three spatial directions on one individual part KN-1 is shown to the left. By contrast, correction measures, shown to the right, relating to different spatial directions x, z are carried out in at least two different individual parts, specifically the actuator KN-1′ (in the x-direction) and the fastening mechanism KN-2′ (in the z-direction), which fixes the actuator KN-1′ to a support KN-3′. Following the assembly of the spacers 304, the optical element KN and the actuators KN-1, KN-1′ are put together to form the projection lens 104. Then, the optical face 302 is situated at its desired target position P_{target}.

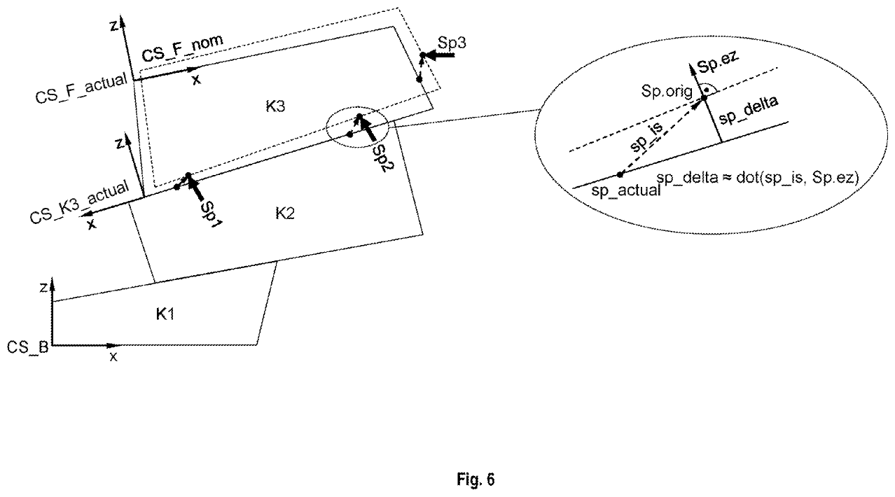

The above-described actual assembly models IMM can be determined with the aid of homogenous coordinates and/or Euler angles, as illustrated below in FIG. 6.

The components K1, K2 (corresponds to KN-1) and K3 (corresponds to KN-1) are arranged in a manner deviating from respective target positions (also referred to as “design” or “target pose” below) on account of manufacturing tolerances.

Hence, the problem arising is that of determining the thicknesses that the positioning elements Sp1, Sp2 and Sp3 (corresponding to the spacers 304 for example) should have so that the functional face CS_F_actual is at the target position CS_F_target in relation to the base CS_B, and to be precise more accurately than the summation of the manufacturing tolerances, usually even more accurately than any individual manufacturing tolerance.

The coordinate system CS_K represents the body K (virtualization) and is defined by: CS.orig=origin, CS.ex=X-axis, CS.ey=Y-axis and CS.ez=Z-axis, where (CS_K)\hat{ }B refers to the coordinates of CS_K in CS_B.

The following calculation example should illustrate this:

Target positions given in CS_B:

(CS_F_target)\hat{ }B = [95, 200, 305] mm, Ry = −14°

```
CS_F_target = name: ‘CS_F’
  base: ‘CS_Base’
  orig: [95 200 305]
    ex: [ 0.9703 0 0.2419]
    ey: [ 0 1 0 ]
    ez: [−0.2419 0 0.9703]
```

3 Spacer-reference points and effective directions:

| Sp1 = name: ‘Spc1’ | Sp2 = name: ‘Spc2’ | Sp3 = name: ‘Spc3’ |
|---|---|---|
| base: ‘CS_Base’ | base: ‘CS_Base’ | base: ‘CS_Base’ |
| orig: [150 300 190] | orig: [340 300 250] | orig: [410 300 320] |
| ez: [−1 0 2]/sqrt(5) | ez: [−1 0 2]/sqrt(5) | ez: [−1 0 0] |

Let CS_K3 be measured in CS_B:

(CS_K3_actual)\hat{ }B = [103 210 167], Ry = −17°, Rz = 182°

```
CS_K3_actual = name: ‘CS_K3’
  base: ‘CS_Base’
  orig: [103 210 167]
    ex: [−0.9557 −0.0298 −0.2928]
    ey: [ 0.0334 −0.9994 −0.0072]
    ez: [−0.2924 −0.0167 0.9562]
```

Let CS_F be measured in CS_K3_actual:

(CS_F_actual)\hat{ }K3 = [−25 0 126] mm, Ry = −5°, Rz = 179°

```
CS_F_actual_K3 = name: ‘CS_F’
  base: ‘CS_K3’
  orig: [−25 0 126]
    ex: [−0.9960 0.0175 −0.0871]
    ey: [−0.0174 −0.9998 −0.0015]
    ez: [−0.0872 0 0.9962]
```

Calculation of the actual pose or actual position of CS_F in CS_B by way of a coordinate transformation from CS_K3 to CS_B, e.g., in homogenous coordinates:

(CS_F_actual)\hat{ }B = K3_2_B * (CS_F_actual)\hat{ }K3

| K3_2_B = | | | |
|---|---|---|---|
| −0.9557 | 0.0334 | −0.2924 | 103.0000 |
| −0.0298 | −0.9994 | −0.0167 | 210.0000 |
| −0.2928 | −0.0072 | 0.9562 | 167.0000 |
| 0 | 0 | 0 | 1.0000 |

with the 4×4 transformation matrix K3_2_B

CS_F_actual = name: ‘CS_F’

```
base: ‘CS_Base’
orig: [90.0542 208.6420 294.7950]
  ex: [ 0.9780 0.0137 0.2082]
  ey: [−0.0163 0.9998 0.0109]
  ez: [−0.2080 −0.0140 0.9780]
```

Offset CS_F_actual from CS_F target in CS_B coordinates (IS_abs) and CS_F target coordinates (IS_rel), and assessment of the actual pose or actual position (comparison with the specification Tol_rel):

Pose CS_F wrt CS_Base:

| [mm, mrad] | Tx | Ty | Tz | Rx | Ry | Rz |
|---|---|---|---|---|---|---|
| Target: | 95.000 | 200.000 | 305.000 | −0.000 | −244.34 | −0.000 |
| Actual: | 90.054 | 208.642 | 294.795 | 14.344 | −209.491 | 16.674 |
| I-S_abs: | −4.946 | 8.642 | −10.205 | 14.344 | 34.855 | 16.674 |
| I-S_rel: | −7.268 | 8.642 | −8.705 | 14.039 | 34.830 | 13.202 |
| Tol_rel: | 2.000 | 2.000 | 1.000 | 5.000 | 5.000 | 2.000 |

Actuator travel calculation in CS_B, where Sp.ez is the unit vector in the effective direction of the positioning element (for example, the effective direction is the thickness in which it should bring about the displacement of K3 into the target position), Sp.orig is the target position of K3 at the reference point (K3-side rest of the positioning element), and sp_actual is the actual position of K3 at the reference point:

```
sp_delta = dot(sp_is, Sp.ez)
where sp_is = Sp.orig − sp_actual
  = spacer point displacement from the actual to the target
    Change [mm]
    Sp1 5.04
    Sp2 11.83
    Sp3 −6.29
```

Although the present disclosure has been described on the basis of exemplary embodiments, it can be modified in various ways.

### LIST OF REFERENCE SIGNS

100A EUV lithography apparatus
100B DUV lithography apparatus
104 Beam-shaping and illumination system
104 Projection system
106A EUV light source
106B DUV light source
108A EUV radiation
108B DUV radiation
110 Mirror
112 Mirror
114 Mirror
116 Mirror
118 Mirror
120 Photomask
122 Mirror
124 Wafer
126 Optical axis
128 Lens element
130 Mirror
132 Medium
200 Data processing apparatus
202 Virtualization unit
204 Determination unit
206 Measuring device
208 Measuring device
210 Computer device
212 CNC milling device
300 Base
302 Optically effective face
304 Spacer
306 Force frame
308 Optical element
ABD Construction data
IMM Actual assembly model
KOM Correction measure
K1-KN Individual parts
P_{target} Target position
P_{actual}Actual position
P_{actual_KN-1} Actual position
P_{actual_K2} Actual position
MEM Mechanical measurement data
M1 Mirror
M2 Mirror
M3 Mirror
M4 Mirror
M5 Mirror
M6 Mirror
OEM Optical measurement data
SMM Target assembly model
S700-S716 Method steps
V Gap

What is claimed is:

1. A method, comprising:
a) measuring individual parts K1-KN of an optical system to provide measurement data, N being greater than one;
b) using the measurement data to virtualize the individual parts K1-KN and using the virtualized individual parts K1-KN to generate an actual assembly model by geometrically stringing together a plurality of the virtualized individual parts K1-KN, the actual assembly model comprising virtual actual positions of the virtualized individual parts K1-KN in a virtually assembled state;
c) using the actual assembly model and a target assembly model to determine a correction measure, the target assembly model comprising virtual target positions of one or more of the virtualized individual parts K1-KN in the virtually assembled state; and
d) using the correction measure, assembling the individual parts K1-KN to form the optical system.

2. The method of claim 1, further comprising:
geometrically stringing together the virtualized individual parts K1-KN to generate the actual assembly model; and
comparing the virtual actual position of a virtualized individual part KN and the virtual target position of the virtualized individual part KN to determine the correction measure.

3. The method of claim 1, further comprising:
fixing the virtualized individual parts K1 and KN at their target positions from the target assembly model to generate the actual assembly model;
geometrically stringing together the virtualized individual parts K2-KN-1 with K1 and/or KN; and
determining the correction measure based on virtual actual positions of at least two virtualized individual parts K2-KN-1.

4. The method of claim 1, wherein d comprises applying the correction measure to the individual part KN-1 or to a region between the individual parts KN-1 and KN.

5. The method of claim 1, wherein d) comprises applying the correction measure to the individual part KN-1 or to a gap between the individual parts KN-1 and KN.

6. The method of claim 1, wherein at least one of the following holds:
the individual part KN comprises an optical element; and
the individual part KN-1 comprises a member selected from the group consisting of a mechanical component, a mechatronic component and a bearing.

7. The method of claim 1, wherein at least one of the following holds:
the individual part KN comprises a member selected from the group consisting of a mirror, a lens element, an optical grating, a waveplate, a stop and a sensor; and
the individual part KN-1 comprises a member selected from the group consisting of a mechanical component, a mechatronic component and a bearing.

8. The method of claim 1, wherein determining the correction measure comprises:
inserting a spacer between two of the individual parts K1-KN; and
adjusting a play of a fastening mechanism which fastens two of the individual parts K1-KN to one another, and/or adjusting an operating point of a mechatronic component as constituent part of one of the individual parts K1-KN.

9. The method of claim 8, wherein the mechatronic component comprises an actuator, and determining the correction measure is determined based on an available actuator travel of the actuator.

10. The method of claim 1, wherein N>5 or 10.

11. The method of claim 1, wherein c) comprises determining a gap between two of the individual parts K1-KN, and d) comprises inserting a spacer into the gap.

12. The method of claim 1, wherein the correction measure relates to at least a first degree of freedom and a second degree of freedom which is different from the first degree of freedom.

13. The method of claim 12, wherein d) comprises applying the correction measure to:
to a first individual part K1-KN;
between a first pair of individual parts K1-KN for the first degree of freedom and a second of the individual parts K1-KN; or
between a second pair of individual parts K1-KN for the second degree of freedom.

14. The method of claim 1, further comprising:
measuring the assembled optical system to provide assembly measurement data;
comparing the assembly measurement data and the target assembly model to determine a further correction measure; and
based on the further correction measure, aligning one or more of the individual parts K1-KN.

15. The method of claim 1, further comprising, after assembling the optical system, operating the optical system.

16. The method of claim 15, wherein the optical system comprises a lithography apparatus.

17. The method of claim 1, wherein the optical system comprises a lithography apparatus.

18. The method of claim 17, further comprising:
geometrically stringing together the virtualized individual parts K1-KN to generate the actual assembly model; and
comparing the virtual actual position of the virtualized individual part KN and the virtual target position of the virtualized individual part KN to determine the correction measure.

19. One or more machine-readable hardware storage devices comprising instructions that are executable by one or more processing devices to perform operations comprising the method of claim 1.

20. A system, comprising:
one or more processing devices; and
one or more machine-readable hardware storage devices comprising instructions that are executable by the one or more processing devices to perform operations comprising the method of claim 1.
